(19) United States
(12) Patent Application Publication
(10) Pub. No.: US 2026/0201562 A1
(43) Pub. Date: Jul. 16, 2026

(54) REACTOR FOR MPCVD APPARATUS

(71) Applicant: WAVE POWER TECHNOLOGY INC., Toufen City (TW)

(72) Inventor: Hsuan-Hao TENG, Toufen City (TW)

(73) Assignee: WAVE POWER TECHNOLOGY INC., Toufen City (TW)

(21) Appl. No.: 19/020,481

(22) Filed: Jan. 14, 2025

(51) Int. Cl. C23C 16/511; C23C 16/44; C23C 16/458

(52) U.S. Cl. CPC C23C 16/511; C23C 16/4409; C23C 16/4586

(57) ABSTRACT

A reactor for an MPCVD apparatus comprises a casing and a stage. The casing comprises an inner bottom surface, an inner top surface, and an inner annular wall surface. The inner top surface and the inner bottom surface are spaced apart from and face towards each other. The inner top surface protrudes towards the inner bottom surface. Two ends of the inner annular wall surface are connected to the inner top surface and the inner bottom surface respectively, thereby forming a reacting cavity among the inner bottom surface, the inner top surface, and the inner annular wall surface. A microwave field formed from a microwave would be in the reacting cavity. The stage is disposed in the reacting cavity and has a carrying surface, and the carrying surface faces towards the inner top surface. The reactor would prevent the generated plasma from being unstable to reduce affection on the MPCVD reaction.

### BACKGROUND

### 1. Field of the Invention

The present invention relates to a device of an MPCVD apparatus, especially to a reactor for an MPCVD apparatus that is capable of preventing two strong field regions from appearing in the microwave field during use.

### 2. Description of the Prior Arts

Microwave plasma assisted chemical vapor deposition (MPCVD) is a method of chemical vapor deposition which is to excite the reaction gases with the strong field region generated by the microwave in a microwave field, thereby forming plasma having a high temperature. The free atoms would be guided to attach onto a certain object and be packed to form a certain structure according to a certain atomic arrangement. A common usage of MPCVD is to produce artificial diamonds. During such process, the plasma generated by hydrogen guides the atomic carbons of methane ionizing, and the carbons are deposited on a seed crystal and packed under a certain atomic arrangement to form/grow a diamond. There are three main types of reactors in the conventional MPCVD apparatus including cylindrical-cavity, Plassys, and TM021-mode-cavity. Among the three types, the TM021-mode-cavity reactors further have multiple different designs.

With reference to FIG. 5, which is one of the designs of a TM021-mode-cavity reactor 90 in the conventional MPCVD apparatus, and since the microwave field generated therein would have a better uniformity, the TM021-mode-cavity reactor 90 is favored and widely adopted. However, during the MPCVD reaction, in addition to a growing region 92 above the stage 91, the microwave field in the cavity structure 90 would form another primary strong field region 93 at a site adjacent the top of the cavity, which usually leads to plasma unstable with two plasma balls located up and down simultaneously, and interferes with the deposition. Furthermore, it can be observed that the growing region 92 formed above the stage 91 by the microwave field in the conventional TM021-mode-cavity reactor 90 is high, and a contact area of a bottom of the growing region 92 in contact with the stage 91 is small, such that the peripheral part and the central part of the semi-finished diamond grow at different rates during the deposition, resulting in stress accumulated in the final product and thus breakage of the product.

To overcome the shortcomings, the present invention provides a reactor for an MPCVD apparatus to mitigate or obviate the aforementioned problems.

### SUMMARY

The main objective of the present invention is to provide a reactor for an MPCVD apparatus that prevents the microwave field from forming two strong field regions and from making the generated plasma unstable.

The reactor for an MPCVD apparatus, which is configured to form a microwave field with a microwave, comprises a casing and a stage. The casing has an inner bottom surface, an inner top surface, and an inner annular surface. The inner bottom surface and the inner top surface are round and spaced apart from and facing towards each other, a diameter of the inner bottom surface is greater than a diameter of the inner top surface, and the inner top surface protrudes towards the inner bottom surface. Two ends of the inner annular wall surface are connected to the inner top surface and the inner bottom surface respectively, thereby forming a reacting cavity among the inner bottom surface. The inner top surface, the inner annular wall surface, and the microwave field are located in the reacting cavity. The stage is disposed in the reacting cavity and has a carrying surface, and the carrying surface faces towards the inner top surface.

With the shape of the reacting cavity, the microwave field formed by the microwave would generate the growing region above the stage, and since the growing region is below the inner top surface, the protruding inner top surface would prevent the microwave field from forming another strong field region above the growing region. Therefore, the reactor would prevent the generated plasma from being unstable.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a reactor for an MPCVD apparatus in accordance with the present invention;

FIG. 2 is a cross-sectional side view of the reactor for an MPCVD apparatus in FIG. 1;

FIG. 3 is a partial enlarged view of the reactor for an MPCVD apparatus in FIG. 2;

FIG. 4 is a diagram of simulation result of a microwave field formed in the reactor for an MPCVD apparatus in FIG. 1; and

FIG. 5 is a diagram of simulation result of a microwave field formed in a conventional reactor.

### DETAILED DESCRIPTION

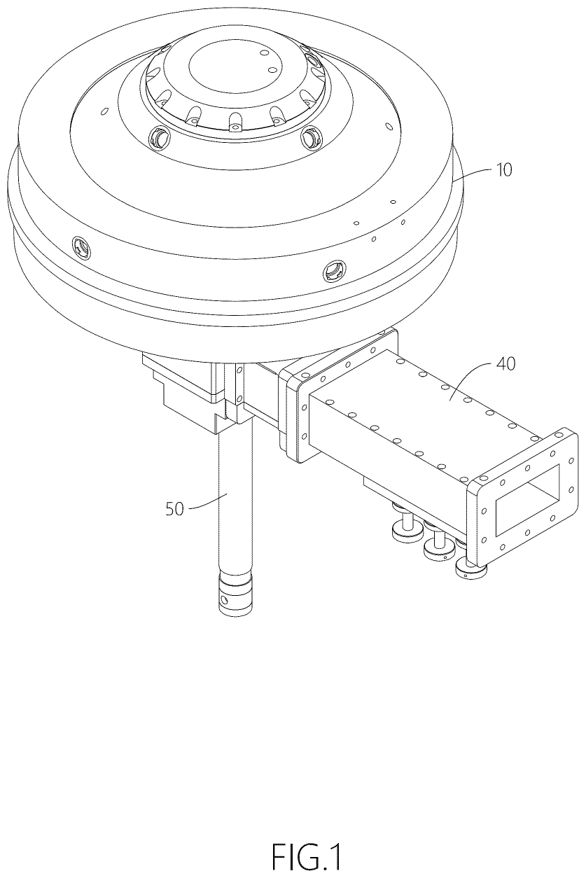

With reference to FIGS. 1 to 4, a reactor for an MPCVD apparatus in accordance with the present invention is configured to form a microwave field with a microwave within. The reactor is preferably applied for the microwave of which a frequency band is from 900 MHz to 930 MHz or from 2400 MHz to 2500 MHz to form the microwave field, but it is not limited thereto.

The reactor for an MPCVD apparatus comprises a casing 10, a stage 30, a waveguide tube 40, and a cooling device 50.

The casing 10 comprises an inner bottom surface 21, an inner top surface 22, and an inner annular wall surface 23. The inner bottom surface 21 and the inner top surface 22 are round. Two ends of the inner annular wall surface 23 are connected to the inner bottom surface 21 and the inner top surface 22 respectively, and thereby the inner bottom surface 21, the inner top surface 22, and the inner annular wall surface 23 together surround and form a reacting cavity 20, and the microwave field formed by the microwave is in the reacting cavity 20.

The inner bottom surface 21 and the inner top surface 22 are spaced apart from and face towards each other. The inner bottom surface 21 and the inner top surface 22 in this embodiment are round surfaces, and a diameter of the inner bottom surface 21 is greater than a diameter of the inner top surface 22, thereby the reacting cavity 20 forming an inverted saucer shape with a smaller top surface and a larger bottom surface. The inner top surface 22 is a reflecting surface which is provided to reflect the microwave, and the inner top surface 22 protrudes towards the inner bottom surface 21 and forms an inverted dome-shaped structure, but it is not limited thereto; the inner top surface 22 may be formed in another shape as long as the inner top surface 22 protrudes towards the inner bottom surface 21 and occupies part of the space at a top part of the reacting cavity 20.

In this embodiment, the inner bottom surface 21 further is recessed along a direction away from the inner top surface 22; to be more precise, the inner bottom surface 21 comprises a peripheral portion 211 and a central portion 212. The peripheral portion 211 surrounds and connects with the central portion 212. The central portion 212 is a planar surface and the peripheral portion 211 is an oblique surface, and the peripheral portion 211 is oblique from inside to outside along a radial direction of the inner bottom surface 21 as gradually approaching the inner top surface 22, but it is not limited thereto, as the configuration of the inner bottom surface 21 may be altered according to needs.

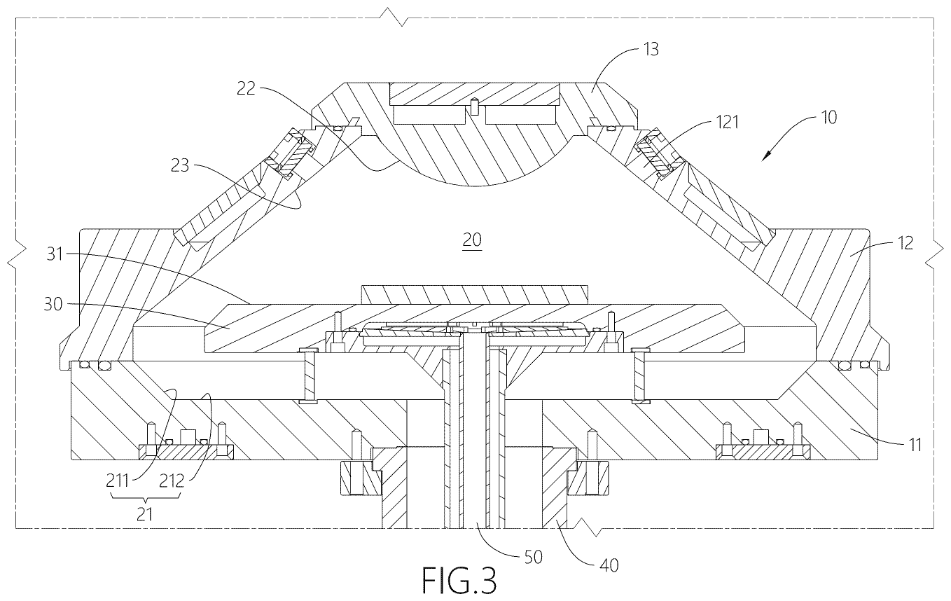

In addition, in this embodiment, an inner diameter of a part of the reacting cavity 20 which is adjacent to the inner top surface 22 gradually decreases along a direction from the inner bottom surface 21 to the inner top surface 22. To be more precise, as shown in FIG. 3, the inner annular wall surface 23 is inclined inwardly along the direction from the inner bottom surface 21 to the inner top surface 22 to form a shape like an inverted funnel, thereby the reacting cavity 20 being truncated cone shaped, but it is not limited thereto, as the shape of the reacting cavity 20 and the configuration of the inner annular wall surface 23 may be altered according to needs. For example, the inner annular wall surface 23 may be a curved surface which is curved along a height direction of the reacting cavity 20, or a stepped surface.

In this embodiment, a bottom disc unit 11, a peripheral wall unit 12, and a top cover unit 13 are combined together to form the casing 10, but it is not limited thereto. The inner bottom surface 21 is located on the bottom disc unit 11, the inner annular wall surface 23 is located on the peripheral wall unit 12, and the inner top surface 22 is located on the top cover unit 13. The peripheral wall unit 12 is sealed and connected to a rim of the bottom disc unit 11 and extends along a direction away from the bottom disc unit 11, and the top cover unit 13 is sealed and mounted on an end of the peripheral wall unit 12 opposite to the bottom disc unit 11.

The top cover unit 13 is preferably mounted on the peripheral wall unit 12 detachably, and there may be multiple said top cover units 13 having the inner top surfaces 22 in different configurations, and thereby the user may change the top cover units 13 according to needs, but it is not limited thereto.

The casing 10 is penetrated to form at least one gas inlet 121. In this embodiment, the at least one gas inlet 121 is formed on the peripheral wall unit 12 located adjacent to the top cover unit 13, but it is not limited thereto; in another embodiment, the at least one gas inlet 121 may be located on the top cover unit 13.

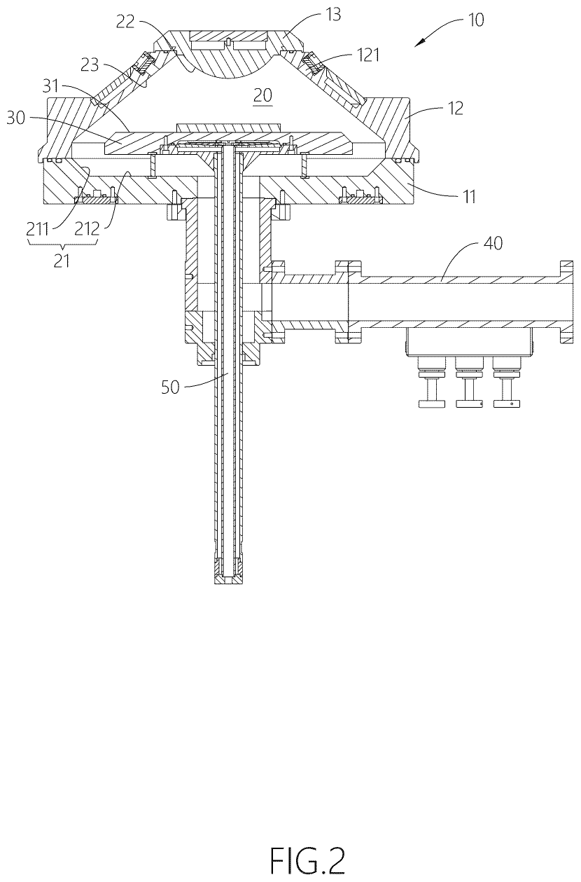

With reference to FIGS. 2 to 4, the stage 30 is disposed in the reacting cavity 20 and has a carrying surface 31 The carrying surface 31 faces towards the inner top surface 22. The stage 30 is configured to set the substrate such as seed crystals of diamond. The substrate may be set on the carrying surface 31 and below the inner top surface 22. In this embodiment, the stage 30 and the inner bottom surface 21 are spaced apart from each other, and a border part of the carrying surface 31 has a chamfering structure, and thus facilitates the working gases (not shown in the drawings) to flow and the microwave propagation to form the microwave field and the plasma, but it is not limited thereto. The waveguide tube 40 is connected to the bottom disc unit 11 and communicates with the reacting cavity 20. The microwave enters or leaves the reacting cavity 20 via the waveguide tube 40. The cooling device 50 is mounted through the casing 10 and connected to the stage 30. To be more precise, the cooling device 50 is a closed flow channel for a coolant to flow within and bring heat away, controlling the plasma at high temperature, but it is not limited thereto.

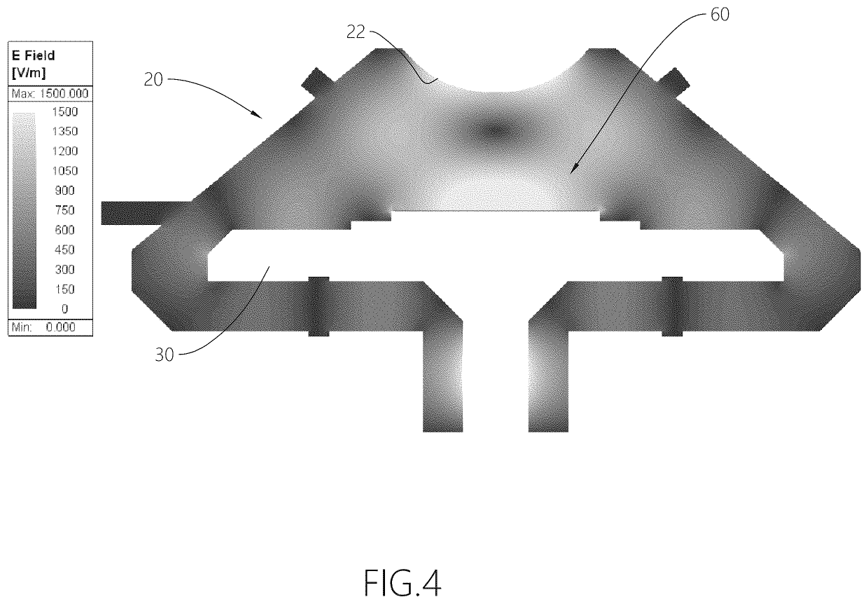

With reference to FIGS. 3 and 4, when the reactor in this disclosure is in use, the microwave field formed by the microwave would generate the growing region 60 which is a strong field above the stage 30 due to the shape of the reacting cavity 20, and since the growing region 60 is below the inner top surface 22, the protruding inner top surface 22 would prevent the microwave field from forming another strong field region above the growing region 60, and thus the reactor in this disclosure may prevent the generated plasma from being unstable and reduce the affection to the MPCVD reaction.

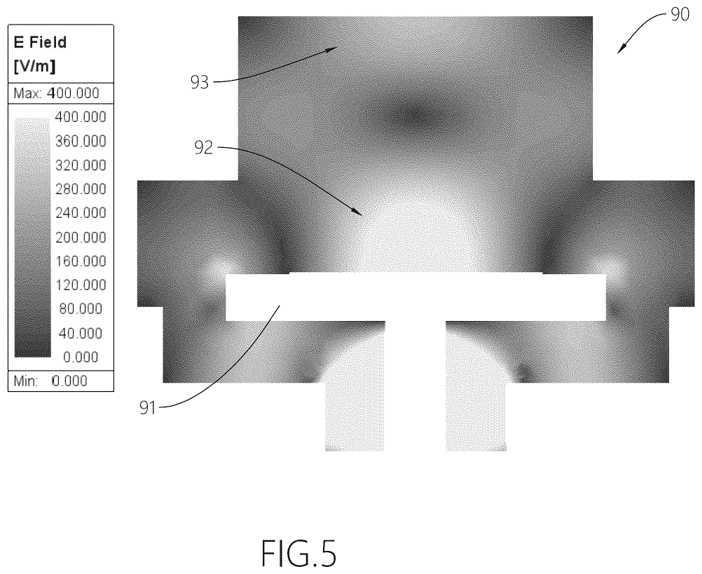

Furthermore, with reference to FIGS. 4 and 5, compared with the prior art, the growing region 60 formed from the microwave field in the reactor in this disclosure may be flatter and broader. Hence, if the user uses the reactors in this disclosure and in the prior art to grow artificial diamonds separately, since the reactor in this disclosure would form a broader growing region 60 than the prior art, even if in the same growing area, the artificial diamond grown in the reactor in this disclosure would have a better uniformity in growing rates between the peripheral part and the central part of the artificial diamond, i.e., the artificial diamond has a much uniform overall growing rate during growth. Therefore, the production yield may be increased thanks to avoiding breakage of the final product caused by the stress accumulated by growing thickness inequality resulting from the inconsistent growing rates. This also represents that the reactor in this disclosure may be applied to produce the product in a larger area to meet the more diverse market needs.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A reactor for a microwave plasma assisted chemical vapor deposition (MPCVD) apparatus configured to form a microwave field with a microwave, and the reactor for the MPCVD apparatus comprising:
a casing having:
an inner bottom surface and an inner top surface being round and spaced apart from and facing towards each other, a diameter of the inner bottom surface being greater than a diameter of the inner top surface, and the inner top surface protruding towards the inner bottom surface; and
an inner annular wall surface, and two ends of the inner annular wall surface connected to the inner top surface and the inner bottom surface respectively, thereby forming a reacting cavity among the inner bottom surface, the inner top surface, and the inner annular wall surface, and the microwave field located in the reacting cavity; and
a stage disposed in the reacting cavity and having a carrying surface, and the carrying surface facing towards the inner top surface.

2. The reactor for the MPCVD apparatus as claimed in claim 1, wherein the inner top surface is inverted dome-shaped.

3. The reactor for the MPCVD apparatus as claimed in claim 1, wherein an inner diameter of a part of the reacting cavity adjacent to the inner top surface gradually decreases along a direction from the inner bottom surface to the inner top surface.

4. The reactor for the MPCVD apparatus as claimed in claim 2, wherein an inner diameter of a part of the reacting cavity surrounded by the inner annular wall surface gradually decreases along a direction from the inner bottom surface to the inner top surface.

5. The reactor for the MPCVD apparatus as claimed in claim 1, wherein the inner bottom surface is recessed along a direction away from the inner top surface.

6. The reactor for the MPCVD apparatus as claimed in claim 4, wherein the inner bottom surface is recessed along a direction away from the inner top surface.

7. The reactor for the MPCVD apparatus as claimed in claim 1, wherein the casing comprises:
a bottom disc unit, and the inner bottom surface located on the bottom disc unit;
a peripheral wall unit sealed and connected to a rim of the bottom disc unit, and extending along a direction away from the bottom disc unit, and the inner annular wall surface located on the peripheral wall unit; and
a top cover unit sealed and mounted on an end of the peripheral wall unit, and said end of the peripheral wall unit opposite to the bottom disc unit.

8. The reactor for the MPCVD apparatus as claimed in claim 6, wherein the casing comprises:
a bottom disc unit, and the inner bottom surface located on the bottom disc unit;
a peripheral wall unit sealed and connected to a rim of the bottom disc unit, and extending along a direction away from the bottom disc unit, and the inner annular wall surface located on the peripheral wall unit; and
a top cover unit sealed and mounted on an end of the peripheral wall unit, and said end of the peripheral wall unit opposite to the bottom disc unit.

9. The reactor for the MPCVD apparatus as claimed in claim 7, wherein the casing further comprises:
at least one gas inlet formed through the peripheral wall unit, and the at least one gas inlet adjacent to the top cover unit.

10. The reactor for the MPCVD apparatus as claimed in claim 8, wherein the casing further comprises:
at least one gas inlet formed through the peripheral wall unit, and the at least one gas inlet adjacent to the top cover unit.

11. The reactor for the MPCVD apparatus as claimed in claim 7, wherein the reactor further comprises:
a waveguide tube connected to the bottom disc unit and fluidly communicating with the reacting cavity.

12. The reactor for the MPCVD apparatus as claimed in claim 10, wherein the reactor further comprises:
a waveguide tube connected to the bottom disc unit and fluidly communicating with the reacting cavity.

13. The reactor for the MPCVD apparatus as claimed in claim 7, wherein the top cover unit is detachably connected to the peripheral wall unit.

14. The reactor for the MPCVD apparatus as claimed in claim 12, wherein the top cover unit is detachably connected to the peripheral wall unit.

15. The reactor for the MPCVD apparatus as claimed in claim 1, wherein the reactor further comprises:
a cooling device mounted through the casing and connected to the stage.

16. The reactor for the MPCVD apparatus as claimed in claim 14, wherein the reactor further comprises:
a cooling device mounted through the casing and connected to the stage.

17. The reactor for the MPCVD apparatus as claimed in claim 1, wherein a frequency band of the microwave is from 900 MHz to 930 MHz or from 2400 MHz to 2500 MHz.

18. The reactor for the MPCVD apparatus as claimed in claim 16, wherein a frequency band of the microwave is from 900 MHz to 930 MHz or from 2400 MHz to 2500 MHz.
